(19) United States
(12) Patent Application Publication
(10) Pub. No.: US 2006/0169982 A1
(43) Pub. Date: Aug. 3, 2006

(54) Liquid crystal display with noise filtering capacitor

(75) Inventors: Gary (Dong-Dong) Shang, Shenzhen (CN); Yu-Hsun Jen, Miao-Li (TW); Ming-Bo Tai, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/317,338

(22) Filed: Dec. 23, 2005

(30) Foreign Application Priority Data
Jan. 28, 2005 (TW) 94201601

(51) Int. Cl. H01L 29/786

(52) U.S. Cl. 257/71

(57) ABSTRACT

A liquid crystal display device includes a first substrate, a second substrate opposite to the first substrate, a liquid crystal layer sandwiched between the first and second substrate. One of the substrates (3) includes a first metal layer (31), an insulative layer (32), and a second metal layer (33) disposed in that order. The first metal layer has an electric potential lower than that of the second metal layer. The first metal layer, the insulative layer, and the second metal layer cooperatively form a filter capacitor. With this configuration, the filter capacitor filters the electrical current passed through the second metal layer. Thus, noise induced by electromagnetic interference is filtrated, which enables the internal signal transmission of the liquid crystal display device to be more reliable.

### FIELD OF THE INVENTION

The present invention relates to liquid crystal display (LCD) devices, and more particularly to an LCD device having high reliability in internal signal transmission.

### BACKGROUND

A conventional LCD device includes a first color filter substrate, a second thin film transistor (TFT) substrate, and a liquid crystal layer disposed between the substrates.

Referring to FIG. 4, this is a schematic, isometric view of part of a conventional LCD device. The LCD device includes a substrate 1, a driving integrated circuit (IC) 18, and a flexible printed circuit (FPC) 16. The substrate 1 can be either a color filter substrate or a TFT substrate of the LCD device. The substrate 1 includes a glass base 10, a first metal layer 11, a first insulative layer 12, a second metal layer 13, a second insulative layer 14, and first and second conductive layers 151 and 152, disposed from bottom to top in that order. The IC 18 is disposed at the first conductive layer 151, and the FPC 16 is disposed at the second conductive layer 152.

The first metal layer 11, the first insulative layer 12, the second metal layer 13, the second insulative layer 14, and the first and the second conductive layers 151 and 152 cooperatively form a plurality of stripe-shaped stacks. The stacks are generally parallel to each other, and are all isolated from each other by a plurality of channels. The stacks correspond to pins 19 of the IC 18 and to contact points (not labeled) of the FPC 16 respectively.

Also referring to FIG. 5, this is a schematic, side cross-sectional view taken along line V-V of FIG. 4. The pins 19 of the IC 18 are electrically connected to the first conductive layer 151 via a first anisotropic conductive film 171 therebetween. The contact points of the FPC 16 are electrically connected to the second conductive layer 152 via a second anisotropic conductive film 172 therebetween.

The second insulative layer 14 defines first through holes 201 corresponding to the pins 19 of the IC 18. A plurality of leads is contained in the first through holes 201, for electrically connecting the first conductive layer 151 and the second metal layer 13. The second insulative layer 14 further defines second through holes 202 corresponding to the contact points of the FPC 16. A plurality of leads is contained in the second through holes 202, for electrically connecting the second conductive layer 152 and the second metal layer 13.

In the substrate 1, the first metal layer 11 is covered by the first insulative layer 12, and is isolated from other elements or circuits of the substrate 1. The first metal layer 11 is used as a spacer to elevate the other elements of the substrate 1. When signals transmit between the IC 18 and the FPC 16 via the second metal layer 13, electromagnetic interference (EMI) is also generated by other internal circuits of the LCD device or by external circuits of an associated device. The EMI induces noise, and the noise is liable to interfere with the signal transmission between the IC 18 and the FPC 16.

Accordingly, what is needed is an LCD device less susceptible to electromagnetic interference.

### SUMMARY

In an exemplary embodiment, an LCD device includes a first substrate, a second substrate opposite to the first substrate, and a liquid crystal layer sandwiched between the first and second substrates. One of the substrates includes a first metal layer, an insulative layer, and a second metal layer disposed in that order. The first metal layer has an electric potential less than that of the second metal layer. The first metal layer, the insulative layer, and the second metal layer cooperatively form a capacitor.

In another embodiment, an LCD device includes a first substrate, a second substrate opposite to the first substrate, and a liquid crystal layer sandwiched between the first and second substrates. One of the substrates includes a first metal layer, an insulative layer, and a second metal layer in that order. The first metal layer is grounded, and has an electric potential less than that of the second metal layer. The first metal layer, the insulative layer, and the second metal layer cooperatively form a capacitor.

With either of these exemplary configurations, the first metal layer, the insulative layer, and the second metal layer cooperatively form a filter capacitor to filter the electrical current passing through the second metal layer. Thus, noise induced by electromagnetic interference generated by other internal circuits of the LCD device or by external circuits of an associated device is filtered by the capacitor. This enables the internal signal transmission of the LCD device to be more reliable.

Other advantages and novel features will become more apparent from the following detailed description when taken in conjunction with the accompanying drawings.

### BRIEF DESCRIPTION OF THE DRAWINGS

FIG. 1 is a schematic, isometric view of part of an LCD device according to an exemplary embodiment of the present invention.

FIG. 2 is a schematic, side cross-sectional view taken along line II-II of FIG. 1.

FIG. 3 is a schematic, side cross-sectional view taken along line III-III of FIG. 1.

FIG. 4 is a schematic, isometric view of part of a conventional LCD device.

FIG. 5 is a schematic, side cross-sectional view taken along line V-V of FIG. 4.

### DETAILED DESCRIPTION OF PREFERRED EMBODIMENTS

An LCD device according to an exemplary embodiment of the present invention includes a first substrate, a second substrate, a liquid crystal layer disposed between the substrates, a driving IC (Integrated Circuit), and an FPC (Flexible Printed Circuit).

Referring to FIG. 1, a substrate 3 can be either the first or the second substrate of the LCD device. The substrate 3 includes a glass base 30, a first metal layer 31, a first insulative layer 32, a second metal layer 33, a second insulative layer 34, and first and second conductive layers 351 and 352 disposed from bottom to top in that order. A driving IC 38 is disposed at the first conductive layer 351, and an FPC 36 is disposed at the second conductive layer 352.

The IC 38 includes a grounding pin 391 and a plurality of functional pins 392. The FPC 36 includes a plurality of contact points (not shown). The glass base 30, the first metal layer 31, and the first insulative layer 32 are each formed essentially as a single plate. The second metal layer 33, the second insulative layer 34, and the first and second conductive layers 351 and 352 cooperatively form a plurality of stripe-shaped stacks. The stacks are generally parallel to each other, and are all isolated from each other by a plurality of channels. The stacks correspond to the pins 391, 392 of the IC 38 and to the contact points of the FPC 36 respectively. The second metal layer 33 defines a grounded portion 330 corresponding to the grounding pin 391, and a plurality of functional portions 331 corresponding to the functional pins 392. The grounded portion 330 is isolated from the functional portions 331.

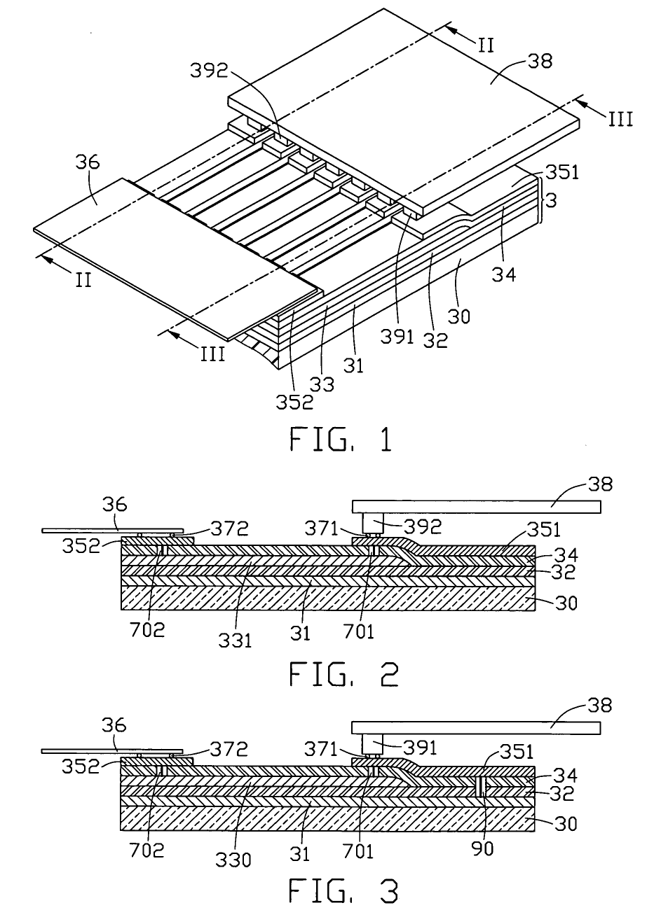

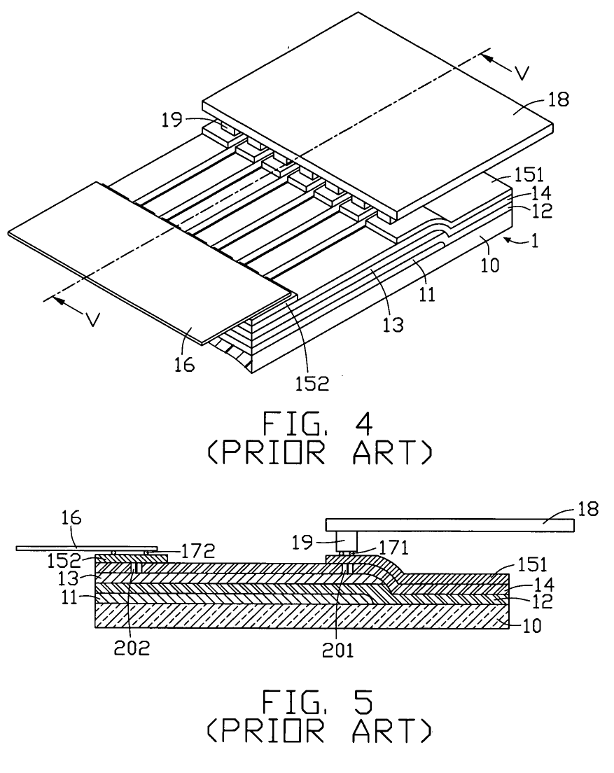

Also referring to FIGS. 2-3, the grounding pin 391 and the functional pins 392 of the IC 38 are electrically connected to the first conductive layer 351 via a first anisotropic conductive film 371 disposed therebetween. The contact points of the FPC 36 are electrically connected to the second conductive layer 352 via a second anisotropic conductive film 372 disposed therebetween.

The second insulative layer 34 defines first through holes 701 corresponding to the pins 391, 392 of the IC 38. A plurality of leads is contained in the first through holes 701, for electrically connecting the first conductive layer 351 and the second metal layer 33. Further, the second insulative layer 34 defines second through holes 702 corresponding to the contact points of the FPC 36. A plurality of leads is contained in the second through holes 702, for electrically connecting the second conductive layer 352 and the second metal layer 33.

The first insulative layer 32 and the second insulative layer 34 cooperatively define a third through hole 90 corresponding to the grounding pin 391. A plurality of leads is contained in the third through hole 90, for electrically connecting the first conductive layer 351 and the first metal layer 31.

In operation, the first metal layer 31 is grounded via the grounding pin 391 of the IC 38, the electric potential of which is zero. The functional portions 331 of the second metal layer 33 are electrically connected to corresponding functional pins 392 of the IC 38, each of which has an electric potential greater than zero. That is, the electric potentials of the functional portions 331 of the second metal layer 33 are greater than the electric potential of the first metal layer 31. The first insulative layer 32 is made of dielectric material. The first metal layer 31, the first insulative layer 32, and the functional portions 331 of the second metal layer 33 cooperatively form a filter capacitor to filter the electrical current passing through the functional portions 331. Noise induced by electromagnetic interference generated by other internal circuits of the LCD device or by external circuits of an associated device is filtered by the capacitor. This enables the internal signal transmission of the substrate 3 of the LCD device to be more reliable.

In an alternative embodiment, the third through hole 90 and the plurality of leads therein can be omitted. In such case, the first metal layer 31 has an electric potential less than that of the second metal layer 33. The first metal layer 31, the first insulative layer 32, and the functional portions 331 of the second metal layer 33 cooperatively form a filter capacitor to filter the electrical current passing through the functional portions 331.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A liquid crystal display, comprising:
a first substrate and a second substrate opposite to each other; and
a liquid crystal layer sandwiched between the first and second substrates;
wherein one of the first and second substrates comprises a first metal layer, a first insulative layer, and a second metal layer disposed in that order, the first metal layer has an electric potential lower than that of the second metal layer, and the first metal layer, the first insulative layer, and the second metal layer cooperatively form a capacitor.

2. The liquid crystal display as claimed in claim 1, wherein the first metal layer is grounded.

3. The liquid crystal display as claimed in claim 2, further comprising a driving integrated circuit (IC) disposed at the second metal layer.

4. The liquid crystal display as claimed in claim 3, wherein the driving IC comprises a grounding pin and a plurality of functional pins, and the grounding pin is electrically connected to the first metal layer.

5. The liquid crystal display as claimed in claim 4, wherein the second metal layer comprises a plurality of stripe-shaped portions, which comprise a grounded portion corresponding to the grounding pin and a plurality of functional portions corresponding to the functional pins.

6. The liquid crystal display as claimed in claim 5, further comprising a second insulative layer disposed between the driving IC and the second metal layer, wherein the second insulative layer defines a plurality of through holes, the through holes having leads therein for electrically connecting the grounding pin of the driving IC and the grounded portion of the second metal layer and electrically connecting the functional pins of the driving IC and the and the functional portions of the second metal layer.

7. The liquid crystal display as claimed in claim 5, further comprising a second insulative layer disposed between the driving IC and the second metal layer, wherein the first insulative layer and the second insulative layer cooperatively define a through hole, and the through hole has leads therein for electrically connecting the grounding pin and the first metal layer.
